(19) United States
(12) Patent Application Publication
(10) Pub. No.: US 2018/0138385 A1
(43) Pub. Date: May 17, 2018

(54) METHOD FOR MANUFACTURING BI-TE-BASED THERMOELECTRIC MATERIAL USING RESISTANCE-HEATING ELEMENT

(71) Applicant: HEE SUNG METAL LTD, Incheon (KR)

(72) Inventors: Byeong Hoon YEON, Incheon (KR); Jae-soung PARK, Incheon (KR); Seung Ho YANG, Incheon (KR)

(21) Appl. No.: 15/568,309

(22) PCT Filed: Sep. 25, 2015
(86) PCT No.: PCT/KR2015/010242

§ 371 Date: Oct. 20, 2017

(30) Foreign Application Priority Data
Apr. 21, 2015 (KR) 10 2015 -0055913

(51) Int. Cl. H01L 35/34; H01L 35/18; H01L 35/16

(52) U.S. Cl. CPC H01L 35/34; H01L 35/16; H01L 35/18

(57) ABSTRACT

The present invention relates to a method for manufacturing a Bi—Te-based thermoelectric material. More particularly, the present invention provides a novel manufacturing method capable of improving thermoelectric properties by controlling uniformity of the ribbon composition by precisely controlling the temperature of a rapid solidification process (RSP) used when manufacturing a metallic ribbon.

### TECHNICAL FIELD

The present invention relates to a novel method for manufacturing a Bi—Te-based thermoelectric material for an n- and/or p-type thermoelectric element, wherein temperatures in a rapid solidification process (RSP) are finely controlled to improve the uniformity control of a ribbon composition and thus the thermoelectric performance properties of the thermoelectric material.

### BACKGROUND ART

Thermoelectric technology is generally a solid-state technology for directly converting thermal energy to electric energy and vice versa, and finds applications in the thermoelectric generation field accounting for thermal-to-electric energy conversion and in the thermoelectric cooling field accounting for electric-to-thermal energy conversion. Thermoelectric materials for use in such thermoelectric generation and thermoelectric cooling improve in thermoelectric performance with increasing of thermoelectric properties. The thermoelectric performance of thermoelectric materials is determined by various physical properties including thermoelectromotive force (V), Seebeck coefficient (α), Peltier coefficient (π), Thomson coefficient (τ), Nernst coefficient (Q), Ettingshausen coefficient (P), electrical conductivity (σ), power factor (PF), figure of merit (Z), dimensionless figure of merit (ZT=α 2 σT/κ wherein T is absolute temperature), thermal conductivity (κ), Lorentz ratio (L), electric resistivity (ρ), etc. Particularly, the dimensionless figure of merit (ZT) is an important factor which determines the energy efficiency of thermoelectric conversion. When made of a thermoelectric material having a greater figure of merit (Z=α2σ/κ), a thermoelectric device exhibits a higher efficiency of cooling and electric generation. That is, a thermoelectric material improves in thermoelectric performance with increasing of Seebeck coefficient and electric conductivity or with decreasing of thermal conductivity.

Meanwhile, thermoelectric materials increase in thermoelectric performance with the refinement and homogeneity of grains thereof. To this end, thermoelectric materials are generally formed into powder using a method such as atomization of molten metal, simple pulverization, electrodeposition, chemical co-precipitation, mechanical pulverization, etc.

Atomization of molten metal may be exemplified by spraying molten metal in an inert gas atmosphere in a chamber and allows for mass production, but suffers from the disadvantage of being unable to control particle sizes. Simple pulverization requires a long period of time for making thermoelectric material powder homogeneous in size and is impossible to control particle sizes. Chemical co-precipitation enables the manufacture of fine powder, but the process has difficulty in terms of concentration control. In addition, the resulting power does not exist in an individually separate particle state, but in an agglomerated state. In mechanical pulverization the objective is to pulverize thermoelectric materials by use of the mechanical kinetic energy of spherical balls in an atmosphere-controlled chamber. However, such a process exhibits a slow production rate and has the plausibility of impurity incorporation attributed to the balls. In addition, there are various methods according to steps, including sol-gel methods, etc.

As a related art, Korean Patent No. 10-0228464 discloses a method for manufacturing fine and nearly spherical powders of thermoelectric materials, in which Bi₂Te₃—Sb₂Te₃-based materials are molten and then rapidly quenched by gas atomizing the molten metal with high-pressure nitrogen gas, using a solidification process. Korean Patent No. 10-0228463 also introduces a method in which a Bi₂Te₃-based thermoelectric material is formed into a ribbon shape that is chemically homogeneous thereacross, followed by pressure molding by cold pressing and pressure sintering by hot pressing. Korean Patent No. 10-0382599 discloses a method in which a PbTe-based thermoelectric material is melted and thus rapidly quenched in Cu block, and then pulverized in to powder by ball mill method. In Korean Patent No. 10-0440268, a Bi₂Te₃—Sb₂Te₃-based thermoelectric material is melted and allowed to grow to crystals which are then pulverized into powder by hydrogen reduction treatment. However, such conventional techniques are limited in terms of producing nano-sized powder of homogeneous particle sizes.

### DETAILED DESCRIPTION OF THE INVENTION

### Technical Problem

The present invention has been made in order to solve the above-mentioned problems in the related art and an aspect of the present invention is to provide a novel method for manufacturing a Bi—Te-based thermoelectric material, wherein temperatures in a rapid solidification process (RSP) for use in the manufacture of metal ribbons are finely controlled to improve the uniformity control of a ribbon composition and thus the thermoelectric performance properties of the thermoelectric material.

### Technical Solution

According to one aspect thereof, the present invention provide a method for manufacturing a Bi—Te-based thermoelectric material, comprising the steps of: (i) melting a raw material including at least one first element selected from the group consisting of Bi and Sb and at least one second element selected from the group consisting of Te and Se, and solidifying the melt into a master alloy ingot; (ii) melting the master alloy ingot by use of a resistance heating element, followed by melt spinning to form a metal ribbon; and (iii) pulverizing the metal ribbon into powder, compressing the powder into a preform, and pressure sintering the preform.

Here, the master alloy ingot in the step (i) may be a n-type Bi—Te—Se-based alloy or a p-type Bi—Sb—Te-based alloy either of which has a purity of 5 N or higher.

According to another aspect thereof, the present invention provides a Bi—Te-based thermoelectric material, manufacture by the method.

### Advantageous Effects

By using a resistance heating element that can consistently supply heat and maintain a constant temperature upon the application of a rapid solidification process (RSP) to the manufacture of metal ribbons, the present invention can manufacture metal ribbons across which composition uniformity is more exactly controlled than those manufactured by RSP using a high-frequency heat source. Therefore, the present invention can improve thermoelectric performance properties of B—Te-based thermoelectric materials.

### BRIEF DESCRIPTION OF THE DRAWINGS

FIG. 1 is a conceptual view stepwise illustrating a method for manufacturing a Bi—Te-based thermoelectric material in accordance with an embodiment of the present invention.

FIG. 2 is a photographic image of metal ribbons of the thermoelectric material manufactured in Example 1.

FIG. 3 shows scanning electron photography images of metal ribbons of the thermoelectric material manufactured in Example 1.

FIG. 4 is an image of a thermoelectric material pressure-sintered from the ribbon manufactured in Example 1.

FIG. 5 depicts thermoelectric figures of merit of the n-type and p-type thermoelectric materials prepared in Example 1.

FIG. 6 is an image illustrating the size of nanoblocks in the thermoelectric material manufactured in Example 1.

### MODE FOR CARRYING OUT THE INVENTION

Below, a detailed description is given of the present invention.

The present invention provides a novel method for manufacturing n-type (Bi, Te, Se) and p-type (Bi, Te, Sb)-based thermoelectric materials into metal ribbons, wherein temperatures in a rapid solidification process (RSP) are finely controlled to improve the uniformity control of the ribbon composition and thus the thermoelectric performance properties of the thermoelectric material.

A Bi—Te-based thermoelectric material has the disadvantage that there is a difference in composition between the ribbons formed early and the ribbons formed late from molten metal due to a large density difference between the components Bi and Te, the high volatility of Te, and the low melting point of Bi—Te thermoelectric materials, resulting in a difficulty in controlling composition uniformity across the ribbons.

When a ribbon is conventionally manufactured by R.S.P. using a high-frequency induction heater, the high-frequency induction heater cannot control temperature increments. Hence, not only is it difficult to control the temperature of RSP, but also the low melting points of Bi₂—Te₃-based thermoelectric materials causes the vaporization of Te, thus degrading the thermal properties of the thermoelectric materials and incurring environmental hazards.

In this regard, a resistance heating element that can consistently supply heat and maintain a constant temperature is used to exactly control the temperature of RSP in accordance with the present invention.

The resistance heating element in the present invention is a heat source that is temperature controllable precisely, like a heater. Capable of exactly controlling temperatures below the melting points of Bi₂—Te₃-based materials, such a resistance heating element is used to restrain the vaporization of Te and maintain the uniformity of composition, with the consequent improvement of thermal properties in the thermoelectric materials.

According to the present invention, further, desired compositions of Bi₂—Te₃-based thermoelectric master alloys can be consistently controlled, which allows for the maintenance of uniformity during the formation of ribbons through R.S.P. and brings about outstanding thermal properties in the final products. As a rule, a difference in the cooling rate upon the manufacture of ribbons induces a difference in composition between wheel and free sides. In the present invention, the metal ribbon has a composition consistent across the free side and wheel side thereof (see Tables 1 and 2, below). Thus, the present invention can improve thermoelectric performance by minimizing composition deviation across the ribbon.

In addition, thermal conductivity decreases as nanoblocks become finer, which leads to outstanding thermoelectric figure of merit (zt). In the present invention, the ribbon is improved in thermal properties as the nanoblocks thereof become fine with a size of 500 nm or less according to R. S. P conditions (see FIG. 6).

In greater detail, a material composition containing highly pure Bi, Te, Se, and Sn, each in an agglomerated state with a size of 2-5 mm, is melted and solidified to prepare a master alloy. Then, the master alloy is formed by using a resistance heating element under the temperature control (ca. 650-700° C.) in rapid solidfication process (RSP) into a Bi—Te-based ribbon, having improved composition uniformity, for use in thermoelectric devices. Thereafter, the ribbon is pressure sintered to afford a thermoelectric material having a high density and excellent thermoelectric properties.

Being in the form of amorphous nano-sized powder with homogenous particle sizes, the Bi—Te-based thermoelectric material manufactured using the aforementioned method is of high formability and density, has a homogenous composition, and thus can provide high strength and improved thermoelectric performance for a device made thereof.

<Method for Manufacturing Bi—Te-Based Theremoelectric Material>

Below, a method for manufacturing a Bi—Te-based thermoelectric material in accordance with one embodiment of the present invention will be explained, but does not limit the present invention. Steps in each process may be modified or selectively combined, as needed, before being carried out.

According to a particular embodiment, the method may comprise: (i) melting a raw material including at least one first element selected from the group consisting of Bi and Sb and at least one second element selected from the group consisting of Te and Se and solidifying the melt into a master alloy ingot; (ii) melting the master alloy ingot by use of a resistance heating element, followed by melt spinning to form a metal ribbon; and (iii) pulverizing the metal ribbon into powder, compressing the powder into a preform, and pressure sintering the preform.

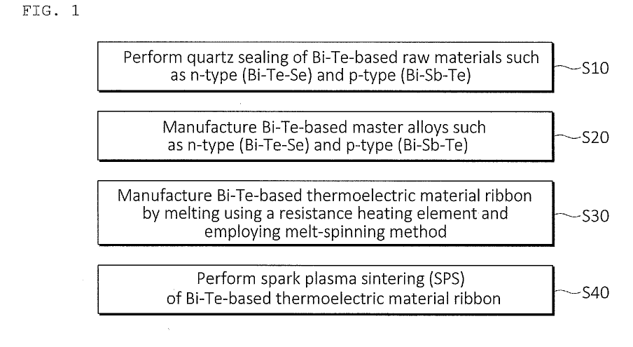

FIG. 1 is a conceptual view stepwise illustrating a method for manufacturing a Bi—Te-based thermoelectric material in accordance with the present invention. The method is explained in a stepwise manner with reference to FIG. 1, as follows.

(i) Components of a Bi—Te-based thermoelectric material are melted and solidified into a master alloy ingot.

This step is to form an n-type and/or p-type Bi—Te-based master alloy.

In detail, step (i) may comprise: (i-1) loading a raw material including a first element and a second element into a quartz tube and then maintaining the quartz tube in a vacuum (‘step S10’); and placing the vacuumed quartz tube in a furnace (e.g., a locking furnace), followed by melting the raw material while oscillating at 650-700° C. for 1-3 hrs at a speed of 10-15 cycles/min to form a master alloy (‘step S20’).

(i-1) First, n-type and p-type thermoelectric materials having respectively predetermined compositions are loaded into a quartz tube and the quartz tube is sealed (hereinafter referred to as “step S10”).

A thermoelectric material available in the present invention may have a composition which includes Bi and Te as main components and Se or Sb as a supplement depending on n- or p-type. Particularly, the material may include (i) at least one first element selected from the group consisting of Bi and Sb; and at least one second element selected from the group consisting of Te and Se.

In greater detail, an n-type thermoelectric material may be a Bi—Te—Se-based alloy composition comprising 50-55 wt % of Bi, 40-45 wt % of Te, and 3-4 wt % of Se, based on the total weight thereof. A p-type thermoelectric material may be a Bi—Sb—Te-based alloy composition comprising 10-15 wt % of Bi, 25-30 wt % of Sb, and 55-60 wt % of Te.

The thermoelectric material to be manufactured in the present invention may further comprise at least one metal selected from the group consisting of Sn, Mn, Ag, and Cu. Doping with at least one of those metals may enhance electric conductivity or Seebeck characteristics. No particular limitations are imparted to the content of the at least one doping metal. For instance, it may be used in an amount of 0.001-1 wt %, based on the total weight of the thermoelectric material.

In the present invention, the thermoelectric components are not particularly limited in terms of size and morphology, but each may be in an agglomerated form ranging in size from about 2 to 5 mm. In addition, the thermoelectric components may particularly have a purity of as high as or higher than 5 N.

After the thermoelectric material is loaded into the quartz tube, the tube is sealed and vacuumed with the aid of a vacuum pump.

(i-2) The material within the quartz tube of step S10 is prepared into n-type or p-type master alloy in a furnace (a rocking furnace) (hereinafter referred to as “step S20”)

In a particular embodiment of step S20, the sealed, vacuumed quartz tube was placed in a furnace and oscillated at a speed of 10-15 cycles/min for 1-3 hrs at 650-700° C. to melt the material to form a master alloy.

A uniform Bi₂—Te₃-based mater alloy is needed for obtain a ribbon by use of a rapid solidification process (R.S.P.). In this regard, a master alloy with a size of Ø 30*100 mm or about Ø 20-30*100-150 mm may be prepared in the present invention.

The master alloy ingot prepared in step S20 may be an n-type Bi—Te—Se-based alloy or a p-type Bi—Sb—Te-based alloy with a purity of as high as or higher than 5 N.

(ii) The n- and/or p-type master alloy obtained in step S20 is melt spun into a metal ribbon (hereinafter referred to as “step S30”).

In this step, the master alloy is molded into a ribbon using a rapid solidification process (RSP).

In a particular embodiment of step S30, the master alloy ingot is mounted in a nozzle of a melt spinning machine, and completely melted using a resistance heating element that can provide heat and consistently maintain a predetermined temperature. Afterwards, a compressed inert gas is sprayed over the melt which is then brought into contact with the surface of the high-speed rotating wheel and thus rapidly quenched. As a result, a Bi—Te-based metal ribbon is formed.

Here, the resistance heating element is not particularly limited as long as it can consistently provide heat to maintain a predetermined temperature. A conventional resistance heating element known in the art may be used. For example, a resistance heating element that generates heat with the supply of electric currents thereto may be employed.

Examples of available resistance heating elements include an electric furnace-type heater. The temperature can be controlled by the heater. In this regard, the heater may maintain the temperature in a range of from 0 to 800° C. and particularly in a range of from 500 to 700° C. The surface resistance of the resistance heating element may be controlled depending on the thickness and kind thereof and may be in the range of 0.1 to 100 ohm (Ω).

Following the preparation of a master alloy from a Bi₂—Te₃-based thermoelectric material, a metal ribbon is conventionally obtained using RSP. Because the elements in the Bi₂—Te₃-based thermoelectric material have low melting points, a high-frequency heat source that cannot control temperature increments is impossible to use in temperature control. If the high-frequency heat source is used, there occurs the problem of Te vaporization and non-uniform composition.

In contrast, the present invention employs a resistance heating element to melt the master alloy under temperature control, thus suppressing the vaporization of Te and allowing for the production of uniform metal ribbons. Therefore, the present invention can enhance thermal properties of the final product.

No particular limitations are imported to the temperature range of the heat that the resistance heating element generates so long as it completely melt the master alloy ingot. Particularly, the temperature range may be from 650 to 700° C.

The kind and the compression range of the inert gas are not particularly limited. For example, argon gas may be particularly sprayed at a pressure of 0.1 to 0.5 MPa.

Further, the high-speed rotating wheel that comes to contact with the melt may be a typical wheel well known in the art, for example a Cu wheel. Here, the rotating speed of the high-speed wheel is not particularly limited. When the wheel rotates at a speed of 500 to 2,000 rpm, the melt brought into contact with the wheel surface is rapidly quenched with the concomitant formation of an alloy ribbon 10 μm or less in thickness.

The master alloy does not become crystalline, but is solidified to a phase in which amorphous structures and crystalline structures are intermixed. When rapid solidification is performed at a very high speed, the alloy can be formed into a ribbon. The solidification speed may be adjusted to produce a semi-ribbon phase in which powder particles with a size of hundreds nanometers are simply interconnected. Afterwards, the metal ribbon is recovered and shortly pulverized into fine powder.

Here, control can be made of homogeneous particle sizes by adjusting the quenching rate and spraying pressure applied to the molten master alloy. Generally, when quenching is slowly performed, nano-sized amorphous powder can be produced while a high spraying pressure accounts for the production of fine powder. In addition, production conditions may vary depending on concentrations and kinds of the raw materials.

Through step S30, a thermoelectric ribbon that is thin, particularly 10 μm or less in thickness, is formed.

(iii) Subsequently, the metal ribbon obtained in step S30 is pulverized and compressed into a preform, followed by pressure sintering the preform to afford a high-density thermoelectric material (hereinafter referred to “step S40”).

In step S40, a predetermined preform is prepared to secure a high density in a pressure sintering process.

For this, the highly brittle material in a ribbon shape that has been rapidly solidified by directly spraying the molten master alloy of step S30 is pulverized into nano-sized amorphous powder with homogeneous particle sizes, and the powder is compressed. In this regard, a typical method known in the art may be used for the compression process. For example, a forming press or a compressor may be particularly employed. Further, a typical condition known in the art may be established for the compression without particular limitations imparted thereto. For example, the powder may be compressed at a pressure of 10 MPa or less and particularly at a pressure of 3 to 10 MPa.

Subsequently, the preform is pressure sintered to produce a high-density thermoelectric material.

Non-illustrative examples of the pressure sintering method available in the present invention include hot pressure forming using, for example, hot press (HP) or spark plasma sintering (SPS).

No particular limitations are imparted to the temperature of hot processing. For example, the preform is particularly sintered at a temperature of 400 to 500° C. for 3 to 10 min under a pressure of 40 to 60 MPa. When the conditions (temperature, time, and pressure of the hot processing are below 400° C., 3 min or 40 MPa, respectively, a high-density material cannot be obtained. On the other hand, when the condition exceeds 500° C. or 10 min, Te increases in vapor pressure and thus volatilizes, deviating from a target composition. As a result, the product is likely to degrade in figure of merit. Further, a pressure higher than 60 MPa may bring about a damage to the mold or apparatus used.

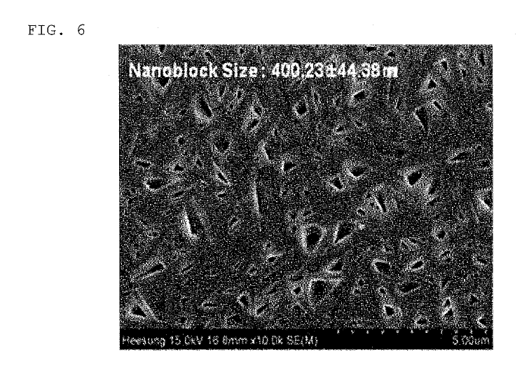

The Bi—Te-based thermoelectric material manufactured by the method described above has a density of 95-99% and particularly about 97% or higher, and a thermoelectric figure of merit of about 1.1-1.4 for p type, and about 0.8-1.1 for n type, and particularly 1.4 for p type and 1.1 for n type (see FIG. 5). This seems to be attributed to the fact that thermal conductivity decreases as nanoblocks become finer in the ribbon prepared by the rapid solidification process (R.S.P), which leads to increasing ZT

ZT=Powder factor*electric conductivity/thermal conductivity (ZT: thermoelectric performance, thermoelectric figure of merit) [Math Equation 1]

A better understanding of the present disclosure may be obtained through the following examples which are set forth to illustrate, but are not to be construed as limiting the present disclosure.

### Example 1

Prepared were thermoelectric materials comprising Bi, Te, Se and Sn, each being in an agglomerated state with a size of about 2-5 mm and a purity of 5 N or higher. For an n-type material, a Bi—Te—Se-based material had a target composition containing 53 wt % of Bi, 44 wt % of Te, and 3 wt % of Se. A p-type material was set to comprise 13 wt % of Bi, 28 wt % of Sb, and 59 wt % of Te. The corresponding thermoelectric material was loaded into a quartz tube which was then sealed with the aid of a vacuum pump. The quartz tube was placed in a locking furnace and heated at about 700° C. for 2 hrs while oscillating at a speed of 10 cycles/min to melt the material which was then cast into a master alloy ingot with Ø 30*100 mm. Subsequently, the master alloy ingot was mounted in a nozzle of a melt spinning machine, and completely melted at about 700° C. using a resistance heating element (a graphite heater, structured to surround the nozzle). Afterwards, a compressed inert gas was sprayed at a pressure of 0.2 MPa over the melt which was then brought into contact with the surface of the rotating Cu wheel and thus rapidly quenched. As a result, a Bi—Te-based metal ribbon was formed. Here, the Cu wheel rotated at a speed of 1,000 rpm.

Thereafter, the metal ribbon was subjected to spark plasma sintering (SPS) which was conducted for 3 min at about 485° C. under a pressure of 50 MPa to afford a thermoelectric material having a density of as high as or higher than 97%.

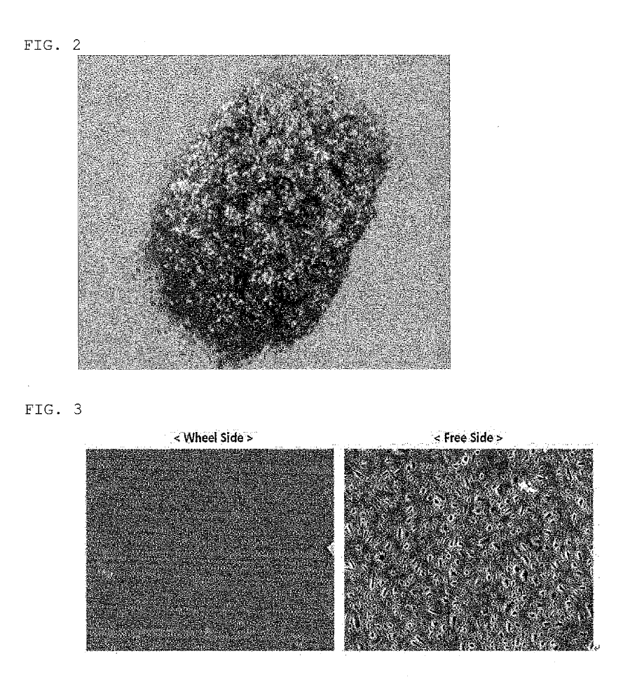

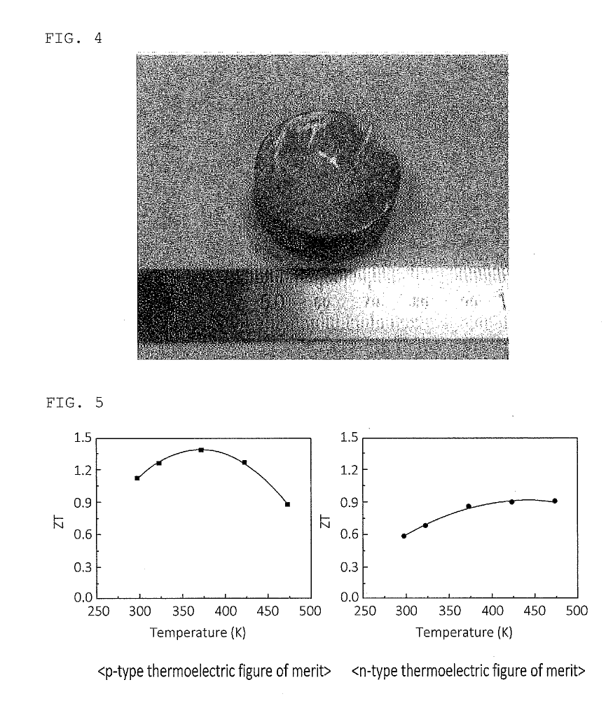

Photographic images and scanning electron microphotography images of the metal ribbon made of the thermoelectric material in Example 1 are given in FIGS. 2 and 3, respectively and a photographic image of the thermoelectric material hot-sintered from the metal ribbon is shown in FIG. 4.

The compositions of the p- and n-type thermoelectric metal ribbons prepared in Example 1 are summarized in Tables 1 and 2, below. The thermoelectric figures of merit of the n- and p-type thermoelectric materials prepared in Example 1 are depicted in FIG. 5.

TABLE 1

| Element | Target Composition | | Wheel side | Free side |
|---|---|---|---|---|
| Bi | Atom % | 0.44 (8.8) | 12.14 | 11.95 |
| | (at. %) | | | |
| | Weight % | 13.83 ± 5 | 18.71 | 18.44 |
| | (wt. %) | | | |
| Te | Atom % | 3 (60) | 55.32 | 54.8 |
| | (at. %) | | | |
| | Weight % | 57.59 ± 5 | 52.06 | 51.66 |
| | (wt. %) | | | |
| Sb | Atom % | 1.56 (31.2) | 32.54 | 33.25 |
| | (at. %) | | | |
| | Weight % | 28.25 ± 5 | 29.22 | 29.9 |
| | (wt. %) | | | |

TABLE 2

| | | | |
|---|---|---|---|
| | Target | | |
| Element | Composition | Wheel side | Free side |

| | | | | |
|---|---|---|---|---|
| Bi | Atom % | 2 (40) | 39.58 | 40.41 |
| | (at. %) | | | |
| | Weight % | 53.16 ± 5 | 53.52 | 53.87 |
| | (wt. %) | | | |
| Te | Atom % | 2.7 (54) | 49.57 | 51.93 |
| | (at. %) | | | |
| | Weight % | 43.83 ± 5 | 40.93 | 42.27 |
| | (wt. %) | | | |
| Se | Atom % | 0.3 (6) | 10.86 | 7.67 |
| | (at. %) | | | |
| | Weight % | 3.01 ± 5 | 5.55 | 3.86 |
| | (wt. %) | | | |

### Comparative Example 1

Prepared were thermoelectric materials comprising Bi, Te, Se and Sn, each being in an agglomerated state with a size of about 2-5 mm and a purity of 5 N or higher. For an n-type material, a Bi—Te—Se-based material had a target composition containing 53 wt % of Bi, 44 wt % of Te, and 3 wt % of Se. A p-type material was set to comprise 13 wt % of Bi, 28 wt % of Sb, and 59 wt % of Te. The thermoelectric materials were loaded into a quartz tube which was then sealed with the aid of a vacuum pump. The quartz tubes were placed in a locking furnace and heated at about 700° C. for 2 hrs while oscillating at a speed of 10 cycles/min to melt the material which was then cast into a master alloy ingot with Ø 30*100 mm. Subsequently, the master alloy ingot was mounted in a nozzle of a melt spinning machine, and completely melted using a high-frequency coil. Afterwards, a compressed inert gas was sprayed at a pressure of 0.2 MPa over the melt which was then brought into contact with the surface of the rotating Cu wheel and thus rapidly quenched. As a result, a Bi—Te-based metal ribbon was formed. Here, the melting temperature was set to be 650-750° C. in consideration of the properties of the high-frequency coil while the Cu wheel rotated at a speed of 1,000 rpm.

Thereafter, the metal ribbon was subjected to spark plasma sintering (SPS) which was conducted for 3 min at about 485° C. under a pressure of 50 MPa to afford a thermoelectric material.

Thermoelectric figures of merit of the thermoelectric materials prepared in Example 1 and Comparative Example 1 are summarized in Table 3, below.

TABLE 3

| | |
|---|---|
| | Comparative |
| Example 1 | Example 1 |

| | P type | n type | P type | n type |
|---|---|---|---|---|
| Thermoelectric | 1.4 | 0.9 | 1.0 | 0.8 |
| Figure | | | | |
| of Merit | | | | |

1. A method for manufacturing a Bi—Te-based thermoelectric material, comprising the steps of:
(i) melting a raw material including at least one first element selected from the group consisting of Bi and Sb and at least one second element selected from the group consisting of Te and Se, and solidifying the melt into a master alloy ingot;
(ii) melting the master alloy ingot by use of a resistance heating element, followed by melt spinning to form a metal ribbon; and
(iii) pulverizing the metal ribbon into powder, compressing the powder into a preform, and pressure sintering the preform.

2. The method of claim 1, wherein the master alloy ingot in the step (i) is a n-type Bi—Te—Se-based alloy or a p-type Bi—Sb—Te-based alloy either of which has a purity of 5 N or higher.

3. The method of claim 2, wherein the n-type Bi—Te—Se-based alloy has a composition containing 50-55 wt % of Bi, 40-45 wt % of Te, and 3-4 wt % of Se, based on the total 100 wt % thereof, and
the p-type Bi—Sb—Te-based alloy has a composition containing 10-15 wt % of Bi, 25-30 wt % of Sb, and 55-60 wt % of Te, based on the total 100 wt % thereof.

4. The method of claim 1, wherein the raw material in the step (i) further comprises 0.001 to 1 wt % of at least one metal selected from the group consisting of Sn, Mn, Ag, and Cu.

5. The method of claim 1, wherein the step (i) comprises the sub-steps of:
(i-1) loading a raw material composition containing a first element and a second element into a quartz tube, and vacuuming the quartz tube; and
(i-2) placing the vacuumed quartz tube in a furnace, followed by melting the raw material while oscillating at 650-700° C. for 1-3 hrs at a speed of 10-15 cycles/min to form a master alloy.

6. The method of claim 1, wherein step (ii) is carried out by mounting the master alloy ingot in a nozzle of a melt spinning machine, melting the master alloy ingot by use of a resistance heating element, and compressing the melt with an inert gas at a pressure of 0.1-0.5 MPa whereby the melt is brought about into contact with a surface of a high-speed rotating wheel and rapidly quenched.

7. The method of claim 1, wherein the resistance heating element in the step (ii) is an electric furnace-type heater and is maintained at a temperature of 500-700° C.

8. The method of claim 6, wherein the wheel is rotated at a speed of 500 to 2,000 rpm.

9. The method of claim 1, wherein the metal ribbon prepared in step (ii) ranges in thickness from 0.1 to 10 μm.

10. The method of claim 1, wherein the pressure sintering in step (iii) is carried out using a hot press or spark plasma sintering.

11. The method of claim 1, wherein the step (iii) is carried out at a temperature of 400-500° C. for 3 to 30 min under a pressure of 40-60 MPa.

12. The method of claim 1, wherein the pressure-sintered Bi—Te-based thermoelectric material in the step (iii) has a density of 95-99%.

13. A Bi—Te-based thermoelectric material, manufactured by the method of claim 1.

14. The method of claim 1, wherein the pressure-sintered Bi—Te-based thermoelectric material in the step (iii) has a thermoelectric figure of merit of 0.8-1.4.
